(19) United States
(12) Patent Application Publication
(10) Pub. No.: US 2009/0255470 A1
(43) Pub. Date: Oct. 15, 2009

(54) ALD REACTOR

(75) Inventors: Pekka Soininen, Helsinki (FI); Leif Keto, Kauniainen (FI)

Correspondence Address: OLIFF & BERRIDGE, PLC, P.O. BOX 320850, ALEXANDRIA, VA, 22320-4850, US

(73) Assignee: BENEQ OY, Vantaa (FI)

(21) Appl. No.: 12/085,027

(22) PCT Filed: Nov. 16, 2006
(86) PCT No.: PCT/FI2006/050500

§ 371 Date: May 15, 2008

(30) Foreign Application Priority Data
Nov. 17, 2005 (FI) 20055612

(51) Int. Cl. C23C 16/455; C23C 16/00; C23C 16/458

(52) U.S. Cl. 118/728; 118/715

(57) ABSTRACT

The invention relates to a reaction chamber of an ALD reactor which comprises a bottom wall, a top wall and side walls extending between the bottom wall and the top wall which define an inner portion (28) of the reaction chamber. The reactor further comprises one or more feed openings (30) for feeding gas into the reaction chamber and one or more discharge openings (40, 50) for discharging gas fed into the reactor from the reaction chamber. The reaction chamber is characterized in that each side wall of the reaction chamber comprises one or more feed openings (30), in which case all side walls of the reaction chamber participate in gas exchange.

### BACKGROUND OF THE INVENTION

The invention relates to a reaction chamber of an ALD reactor (Atomic Layer Deposition) and to a method of processing a substrate in a reaction chamber of an ALD reactor. More particularly, the invention relates to a reaction chamber of an ALD reactor according to the preamble of claim 1, the reaction chamber comprising a cover plate and a base plate which form an inner portion the inside of the reaction chamber, a bottom wall, a top wall and side walls extending between the bottom wall and the top wall, the reactor further comprising one or more inlet openings for feeding gas into the reaction chamber and one or more discharge openings for discharging the gas fed into the reactor from the reaction chamber.

The reaction chamber is the main component of an ALD reactor where substrates to be processed are placed. An ALD process is based on sequential, saturated surface reactions where the surface controls film growth. In the process, each reaction component is brought separately into contact with the surface. In the reaction chamber, reaction gases are thus supplied over the substrates sequentially with flushing gas pulses in between. Consequently, the flow dynamics of the reaction chamber must be good. Conventional prior art feed-through reaction chambers made of a quartz pipe have a first end, from which reaction gas is fed, and a second end, from which it is pumped out. The flow dynamics of such a tubular reaction chamber (flow distribution) are not sufficiently good as such, but the reactor must be provided with separate flow guides. Even in this case, the material efficiency of such a reaction chamber is poor and the thickness of the film produced on the substrate is uneven. Furthermore, the process is slow in this kind of reaction chamber. An example of such a structure is illustrated in FIG. 2 of U.S. Pat. No. 4,389,973, for instance. Feed-through reaction chambers have also been manufactured of quartz plates, in which case feed pipes, flow guides, mixing pipes, outlets and the space for substrate have been produced by processing the quartz plates. In that case, the reaction chamber and its flow system are formed by connecting the processed plates together, in which case the flow system can be designed freely and the flow distribution controlled better. Also in these solutions, the flow of reaction gases and cleaning gases is guided over the substrate from one side to the other, from which they are absorbed. This easily generates dead ends for the flow at the edges of the reaction chamber and side wall effects in the flow near the walls, which decrease flow dynamics. Furthermore, in structure of this kind, the forming of a reaction chamber produces several surfaces that need to be sealed between the reaction chamber and its environment. Examples of the structure described above are illustrated in FIGS. 1 and 2 in U.S. Pat. No. 6,572,705. The prior art also includes nozzle structures with an “overhead shower head”, where the flow of gases to be fed into the reaction chamber is guided directly towards the substrate, in which case the number of dead surfaces is minimized in the radial direction. A problem associated with this shower reaction chamber is that gas flows hit the substrate surface and the concentration of the starting material acting on the middle portion of the substrate is stronger than that acting on its edge portions. Furthermore, when this flow system is used, it is difficult to design chambers for simultaneous processing of several substrates. An example of the described structure is illustrated in FIGS. 6 and 7 in U.S. Pat. No. 6,902,624.

In all the reaction chambers described above, the object has been to improve the flow dynamics but the result has been a complex structure or a disadvantageous flow distribution, in which case the reaction chamber does not function optimally. Furthermore, passive surfaces of the reaction chamber with no gas feed or discharge tend to wet. In this context, wetting means that the surfaces are subjected to starting material chemicals due to the gases flowing in the reaction chamber, which in turn decreases the material efficiency of the process and may cause corrosion of the reactor surfaces.

In this context, the substrate refers to a material to be processed in a reactor, which may be, for example, a silicon disc or a three-dimensional object made of a solid (dense), porous or powdery material. The reaction space is usually arranged inside a vacuum chamber, or the inner surface of the actual vacuum chamber forms the necessary reaction space, and it may be heated to a temperature of hundreds of degrees. A typical reaction temperature ranges from 200 to 500° C.

### BRIEF DESCRIPTION OF THE INVENTION

The object of the invention is to provide a reaction chamber so as to solve the above-mentioned problems. The solution according to the invention is achieved by a reaction chamber according to the characterizing part of claim 1, which is characterized in that each side wall of the reaction chamber comprises one or more feed openings, in which case all side walls of the reaction chamber participate in gas exchange.

Preferred embodiments of the invention are disclosed in the dependent claims.

The invention is based on providing a feed-through reaction chamber where gas is fed or discharged through each side wall of the reaction chamber. In other words, all side walls are made active, and thus gas may be fed into the reaction chamber through all side walls. It is also feasible to feed and discharge gas through the same side wall. This solution according to the invention may be implemented by providing each side wall with one or more feed openings, which are connected to gas inlets. In an extreme case, the reaction chamber comprises no concrete side walls, but the feed and discharge openings form the side walls of the reaction chamber.

In this context, the feed and discharge openings refer to openings which open into the reaction chamber and through which gas may flow into the reaction chamber and/or out of it. Furthermore, in this context, the inlet and outlets refer to all channels, pipes and the like for supplying the gas to be introduced into the reaction chamber to the feed opening and for discharging the gas to be discharged from the reaction chamber through the discharge opening. Side walls refer to walls of the reaction chamber that extend between the end walls of the reaction chamber. For example, in a cylindrical reaction chamber, the casing forms the side walls and in a cubical reaction chamber, the walls extending between two opposite walls form the side walls. In another polygonal reaction chamber, the walls extending between polygonal end walls form the side walls of the reaction chamber for feeding gas into the reaction chamber. In general, all side walls extend in parallel and perpendicularly to the end walls but in conical solutions, the side walls converge.

An advantage of the method and system according to the invention is that the number and area of surfaces that wet may be reduced considerably by making all side walls of a reaction chamber active for gas feed, which improves the material efficiency of the gases used as no material growth will occur on the walls of the reaction chamber. Furthermore, the flow dynamics of the reaction chamber will also improve, in which case the distribution of the gases fed into the reaction chamber is good and materials are mixed and/or deposited evenly on top of a substrate. The fact that all walls are made active also substantially eliminates back flows and dead-end pockets inside the reaction chamber. In this context, the side wall also refers to walls whose tangent is perpendicular to the tangent of the surface of a planar substrate. It should also be noted that in this context, the upper and lower walls refer to end walls regardless of the position of the reaction space or reaction chamber. In other words, in some embodiments, the upper and the lower wall may be in the vertical position if, for example, the reaction chamber is in the horizontal position while plate-like substrates are in the vertical position. In the case of plate-like or discoid substrates, the side walls are the walls that are substantially vertical to the substrate surface.

### BRIEF DESCRIPTION OF THE FIGURES

The invention will now be described in greater detail by preferred embodiments with reference to the accompanying drawings, in which

FIGS. 1A and 1B illustrate a reaction chamber according to the present invention.

### DETAILED DESCRIPTION OF THE INVENTION

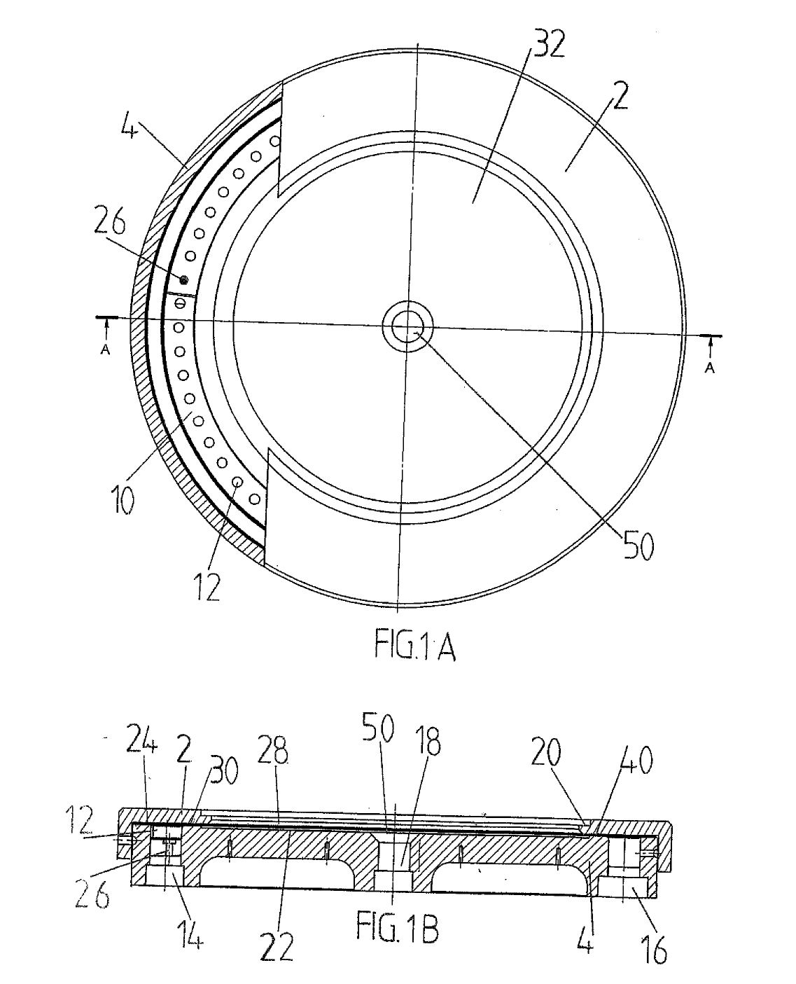

FIGS. 1A and 1B illustrate a cylindrical reaction chamber 1 of an ALD reactor according to the present invention, the reaction chamber comprising a cover plate 2 and a base plate 4. The cover plate 2 and the base plate 4 define a bottom wall, top wall and side walls of an inner portion 28 of the reaction chamber. In the embodiment illustrated in FIG. 1, the cover plate 2 is a circular flange-like plate, which may be placed on and/or fixed tightly to top of the base plate 4 so that it forms the inner portion 28 of the reaction chamber. The side walls of the reaction chamber have been provided with feed openings 30 and discharge openings 40, through which gas may be fed into the inner portion 28 of the reaction chamber and discharged from the inner portion 28 of the reaction chamber. Furthermore, the base plate 4 has been provided with inlets 12 and 14, along which gas may be supplied to the feed openings 30, and outlets 16, along which gas may be discharged from the inner portion 28 of the reaction chamber through the discharge openings 40. There may be one or more inlets 12, 14 and outlets 16. For example, there may be two inlets 14, one of which is intended for reaction gas and the other for a group of starting materials, in which case the inlets may further comprise valve means or the like for closing a desired inlet 14, if necessary.

In the embodiment of FIGS. 1A and 1B, the inlet opening 30 and the discharge opening 40 have been implemented so that a gap is left between the cover plate 2 and the base plate 4, the gap extending along the whole circumference of the side wall of the inner portion 28 of the reaction chamber. In that case, this gap at least partly forms the side walls of the inner portion 28. This gap is further in a flow connection with the inlets 12, 14 and outlets 16, in which case the gap forms an inlet opening 30 and a discharge opening 40 for the inner portion 28 of the reaction chamber.

As can be seen from FIG. 1A, the base plate is provided with a perforated plate 10, which comprises holes 12 at predetermined intervals. The holes of the perforated plate 10 are in a flow connection with the inlets 14, in which case the gas to be fed into the inner portion 28 of the reaction chamber is distributed evenly to the circumferentially extending inlet opening 30. Thus the length of the perforated plate 10 determines the size of the inlet opening 30 in relation to the discharge opening 40 because gas may be fed into the inner portion 28 only over the length of the perforated plate 10 through the holes 12. The ends of the perforated plate are further provided with seals, which substantially prevent gas from flowing from the area between the ends of the perforated plate 10 elsewhere than into the inner portion 28 through the inlet opening. However, to prevent formation of flow pockets, it may be advantageous to leave a certain amount of leak in some cases. In the case of FIG. 1A, the perforated plate 10 extends 180 degrees from the side wall of the cylindrical inner portion 28, in which case the inlet opening is also 180 degrees. This means that the discharge opening 40 is 180 degrees, too. The perforated plate 10, however, comprises pin adjustment means 26 for adjusting the length of the perforate plate 10. For example, by adjusting the size of the perforated plate 10 and thus that of the inlet opening 30 to 220 degrees, in which case the size of the discharge opening correspondingly decreases to 140 degrees, gas feed into the inner portion 28 of the reaction chamber may be enhanced. If the size of the perforated plate 10 and thus that of the inlet opening are adjusted to 140 degrees, in which case the size of the discharge opening increases to 220 degrees, gas discharge from the inner portion 28 of the reaction chamber may be enhanced. An advantage of such adjustability is that the flow may be adjusted to better correspond to the requirements of each starting material. This kind of adjustable perforated plate 10 may, according to FIG. 1A, consist of two overlappable parts which, when adjusted, may slide so that they overlap each other. Adjustment may be carried out by pressing the pin 26 down, in which case the parts of the perforated plate may move into an overlapping position with respect to each other. The holes 12 of the perforated plate 10, from which gas flows to the inlet opening 30, are able to receive the pin 26, for which reason the pin 26 requires no separate holes. Furthermore, the holes 12 are provided in both parts of the perforated plate 10 at the same predetermined intervals, in which case the holes will be aligned in the vertical direction as the parts slide one on top of the other.

The outlet 16 opens near the edge of the base plate 4 as a circumferentially extending groove, which further opens into the discharge opening 40. The outlet does not necessarily require a perforated plate because it is often unnecessary to distribute the discharge flow evenly along the length of the side wall in the same manner as the inlet flow. Naturally, the outlet may also be provided with a perforated plate if it is desirable to achieve a more even suction.

The whole circumferential side wall of the cylindrical reaction chamber is made active in the manner described above, in which case the whole length of the side wall is employed in feeding gas into and discharging it from the inner portion of the reaction chamber. In other words, the whole length of the side wall consists of an inlet or a discharge opening, in which case an inlet opening or a discharge opening extends along the whole length of the side wall. In that case, there are substantially no inactive portions in the side wall.

In accordance with FIG. 1B, the base plate 4 is provided with a holder 22 for receiving a substrate. In this embodiment, the holder 22 is a recession formed in the top surface of the base plate 4, where a thin silicon disc, for example, may be placed for processing. When the silicon disc is placed in the holder 22, it forms an essential part of the bottom wall of the inner portion 28 of the reaction chamber. In this embodiment, the cover plate 2 comprises a circular opening 32 whose edge functions as another holder 22 for receiving another substrate. In that case, a silicon disc, for example, may be placed on top of the edge 20, the silicon disc thereby forming an essential part of the top wall of the inner portion 28 of the reaction chamber. In that case, two silicon discs may be processed simultaneously in the reaction chamber so that the top surface of the silicon disc placed in the holder 22 of the base plate 4 is processed and correspondingly the lower surface of the silicon disc placed in the holder 20 of the cover plate 2. In that case, the silicon discs form most of the surfaces of the reaction chamber that will wet, which minimizes the number of surfaces of the actual cover plate 2 and base plate 4 that wet, which in turn minimizes the undesirable effects of the gases used on the base plate 4 and cover plate 2.

The solution according to FIGS. 1A and 1B may be modified in various ways without departing from the scope of invention defined in the claims. The shape of the inner portion of the reaction chamber may be selected freely and it may be cubical, a rectangular prism, polygonal or have an oval cross section or another suitable geometric shape. If, for example, the inner portion of the reaction chamber is cubical, it comprises four side walls, in which case at least one side wall is provided with inlet openings and the other side walls with discharge openings. The dimensions of the inner portion of the reaction chamber may also be adjusted according to the object or product to be processed. When, for example, a three-dimensional object is processed, the height of the side walls may be increased so that the object fits in the inner portion of the reaction chamber. In that case, the circumferential side wall of the reaction chamber according to FIGS. 1A and 1B, for example, may be stretched by increasing the distance between the cover plate 2 and the base plate 4, in which case the reaction chamber becomes a tubular structure, whose casing forms the side walls of the reaction chamber. In this tubular solution of the reaction chamber, feed openings are formed in the inner wall of the casing by providing it with openings for feeding gas or by making the inner wall of the casing of a porous material, such as sintered metal/ceramic material, which is gas-permeable. In the case of a porous side wall, gas is introduced behind the side wall, from which it penetrates through the porous material into the inner portion of the reaction chamber. Correspondingly, the casing may be provided with discharge openings or discharge may be carried out by absorbing gas through the porous side wall. In the case of porous material, the reaction chamber may be formed of two pipes within each other. The inner one of the pipes is made of a porous material and a reaction space is formed inside it. The casing may be provided with feed openings or porous material so that gas may be fed into the reaction chamber along the whole circumference and length of the casing or only along part of the length or circumference. For example, gas may be fed only along half of the casing circumference along the whole length of the casing. Correspondingly, the discharge openings may be arranged along the whole circumference and length of the casing or only along part of the circumference and/or length of the casing. One alternative is to provide discharge openings in one or both end walls of a cylinder, in which case it is advantageous to feed gas into the reaction space along the whole circumference and length of the casing of the reaction chamber. Furthermore, the ratio of the feeding portion to the discharge portion in the casing may be divided according to the principle described in connection with the perforated plate, in which case the ratio of gas feed to gas discharge may be adjusted by adjusting the ratio of the feeding and discharge areas of the casing. Such an elongated reaction chamber may have an inner diameter of 230 mm and an outer diameter of 300 to 350 mm so that it can receive silicon discs having a diameter of 200 mm. Furthermore, the reaction chamber may be provided with support means, which may receive one or more silicon discs or another substrate for simultaneous processing. If the length of the reaction chamber is increased, it may be used for processing hundreds of silicon discs simultaneously. Furthermore, the silicon discs may be placed so that the gaps between them function as gaps that constrict the flow. In that case, there is no need for a porous/perforated inner pipe. This further simplifies the structure.

Each side wall of the reaction chamber is provided with one or more inlet openings and/or discharge openings. For example, the opposite side walls of the inner portion of a cubical reaction chamber may comprise inlet and discharge openings, respectively. Alternatively, two adjacent walls may comprise inlet openings and the other two adjacent walls discharge openings. In addition, it is feasible to provide only one wall with inlet openings and the other three with discharge openings, or vice versa. The same side wall may also be provided with both discharge and inlet openings. It should further be noted that the length of the reaction chamber may be increased in the same way as in the case of a tubular reaction chamber regardless of the shape of the reaction chamber. A cubical reaction chamber, for example, may be stretched as described above.

The inlet and outlets may further be arranged in a desired manner and their number selected according to the need. Furthermore, the inlet and outlets may also be provided in the cover plate in the same manner as in the base plate. Instead of a perforated plate, another similar means may be used for distributing the incoming flow evenly over a desired length of the side wall. The perforated pipe, base plate or cover plate may also be provided with branched channels or the like. The adjustment means for adjusting the inlets and/or outlets and/or discharge openings and/or discharge openings may also comprise other kind of means, such as flow chokers, valves or movable seals for separating inlet and discharge openings or inlet and outlets from each other in a controlled manner. The adjustment means may adjust the location and/or size and/or number of the feed openings and/or discharge openings and/or the number and/or location of the feed pipes and/or outlets in each side wall or in all side walls or in relation to each other.

The holders for the substrate may also vary considerably. In the case illustrated in FIG. 1A, the cover plate 2 could also be made enclosed, in which case only the holder 22 in the base plate 4 could be used. Correspondingly, only the holder 20 provided in the cover plate could be used. FIGS. 1A and 1B also illustrate a second outlet 18 and discharge opening 50. This discharge opening 50 and outlet 18 may be used only when a silicon disc 2 to be placed in the cover plate is processed. In that case, gas may be introduced into the inner portion 28 of the reaction chamber along the whole length of the side wall. In other words, the side wall comprises no discharge opening but an inlet opening, which extends around the whole side wall, i.e. 360 degrees. In that case, gas enters the inner portion 28 radially from each direction and flows out of the inner portion 28 through the discharge opening 50 in the middle of the base plate 4. Correspondingly, the discharge opening 50 and the outlet 18 could be arranged in the middle of the cover plate 2, in which case only the holders 22 of the base plate 4 would be used for receiving the substrate. In this embodiment, gas flows over the substrate and exits through the discharge opening in the middle.

In the case of FIGS. 1A and 1B, the inlet opening 30 and the discharge opening 40 in the side wall of the inner portion 28 are uniform, thus forming substantially the side walls of the inner portion 28. The inlet opening 30 extends, for example, 180 degrees of the length of the side wall and the discharge opening the rest 180 degrees, in which case the side wall is active along its whole length. Alternatively, the inlet and discharge openings may be formed as holes, cut-to-size gaps or as similar openings arranged in the side walls at predetermined intervals.

It is essential to the invention that gas may be fed through at least one side wall into the inner portion of the reaction chamber and discharged through the other side walls. In that case, the side walls are provided both with inlet and discharge openings. Alternatively, gas may be fed through all side walls, in which case gas is discharged through the bottom or the top wall. In that case, each side wall is provided with inlet openings and the bottom and the top wall with a discharge opening(s). This provides a reaction chamber where all side walls are active.

It will be obvious to a person skilled in the art that, as the technology advances, the inventive concepts may be implemented in various ways. The invention and its embodiments are thus not limited to the examples described above but may vary within the scope of the claims.

1. A reaction chamber of an ALD reactor comprising a bottom wall, a top wall and side walls extending between the bottom wall and the top wall and defining a circumference of the reaction chamber, which bottom wall, top wall and side walls define an inner portion of the reaction chamber, the reactor further comprising one or more feed openings for feeding gas into the reaction chamber and one or more discharge openings for discharging gas fed into the reactor from the reaction chamber, wherein the feed openings and discharge openings are arranged on the circumference defined by the side walls such that the whole length of the circumference is divided into a feeding portion and a discharge portion for feeding gas into the reaction chamber along a part of the circumference and discharging gas from the reaction chamber along the other part of the circumference.

2. A reaction chamber according to claim 1, wherein the reaction chamber is provided with one or more inlets in a flow connection with the feed openings and one or more outlets in a flow connection with the discharge openings.

3. A reaction chamber according to claim 1, wherein the inner portion of the reaction chamber is cylindrical, in which case it comprises one circumferential side wall.

4. A reaction chamber according to claim 1, wherein the inner portion of the reaction chamber is cubical.

5. A reaction chamber according to claim 1, wherein the inner portion of the reaction chamber has the shape of a rectangular prism.

6. A reaction chamber according to claim 1, wherein the inlets and/or feed openings and outlets and/or discharge openings are provided so that gas may be fed into the reaction chamber and/or discharged therefrom along the whole length of the circumferential side wall.

7. A reaction chamber according to claim 1, wherein the outlets and inlets are arranged in a base plate.

8. A reaction chamber according to claim 1, wherein reaction chamber comprises adjustment means for adjusting ratio of the feeding portion and the discharge portion.

9. A reaction chamber according claim 8, wherein the reaction chamber further comprises adjustment means for adjusting the inlets and/or feed openings and/or outlets and/or discharge openings in order to adjust the amount of gas to be fed into the inner portion of the reaction chamber and/or discharged therefrom.

10. A reaction chamber according to claim 9, wherein the adjustment means are arranged to adjust the location and/or size and/or number of the feed openings and/or discharge openings.

11. A reaction chamber according to claim 9, wherein the adjustment means are arranged to adjust the number and/or location of the feed pipes and/or outlets.

12. A reaction chamber according to claim 8, wherein the adjustment means comprise a perforated plate arranged in the inlet for supplying gas to the feed openings through its holes, the length and/or number of holes of the perforated plate being adjustable.

13. A reaction chamber according to claim 1, wherein both the base plate and the cover plate have been provided with holders for a substrate, in which case two substrates may be processed simultaneously.

14. A reaction chamber according to claim 13, wherein the holder provided in the cover plate is arranged so that the substrate placed therein forms at least part of the top wall of the reaction chamber, and the holder provided in the base plate is arranged so that the substrate placed therein forms at least part of the bottom wall of the reaction chamber.
